(19) United States
(12) Patent Application Publication
(10) Pub. No.: US 2021/0167666 A1
(43) Pub. Date: Jun. 3, 2021

(54) COOLING DEVICE

(71) Applicant: Toyota Jidosha Kabushiki Kaisha, Toyota-shi Aichi-ken (JP)

(72) Inventors: Junichi Deguchi, Susono-shi (JP); Eiji Yamada, Owariasahi-shi (JP); Hiroyuki Hattori, Okazaki-shi (JP); Hiroaki Kodera, Toyota-shi (JP); Daisuke Tokozakura, Susono-shi (JP); Satoshi Tominaga, Susono-shi (JP); Yuki Iwama, Fuji-shi (JP)

(21) Appl. No.: 17/107,009

(22) Filed: Nov. 30, 2020

(30) Foreign Application Priority Data
Dec. 3, 2019 (JP) 2019-219005

(51) Int. Cl. H02K 9/19; B60K 11/02; H02K 5/20; H02K 1/32

(52) U.S. Cl. CPC H02K 9/19; H02K 1/32; H02K 5/20; B60K 11/02

(57) ABSTRACT

A cooling device cools a motor mounted on a vehicle and an inverter driving the motor. The cooling device includes: a common flow path through which coolant flows; a first flow path branching from the common flow path and arranged to cool the inverter and a stator of the motor; and a second flow path branching from the common flow path, being independent of the first flow path, and arranged to cool a rotor of the motor. The cooling device further includes a distribution structure configured to distribute the coolant to the first flow path and the second flow path, and to change a distribution ratio of a first coolant distributed to the first flow path out of the coolant and a second coolant distributed to the second flow path out of the coolant.

### CROSS-REFERENCE TO RELATED APPLICATION

This application claims priority to Japanese Patent Application No. 2019-219005 filed on Dec. 3, 2019, the entire contents of which are herein incorporated by reference.

### BACKGROUND

### Technical Field

The present disclosure relates to a cooling device mounted on a vehicle.

### Background Art

Japanese Laid-Open Patent Publication No. JP-2010-064651 discloses a temperature control device for a motor driving system of a vehicle. The motor driving system includes a motor, an inverter for controlling the motor, and a battery for supplying power to the inverter. The temperature control device is provided with a pipe through which cooling water flows. The pipe is arranged to cool the motor, the inverter, and the battery in parallel. When the battery temperature is high, much cooling water is supplied to the battery. On the other hand, when the motor temperature is high, much cooling water is supplied to the motor and the inverter. A distribution ratio of the cooling water distributed to the motor side and the cooling water distributed to the inverter side is constant.

Japanese Laid-Open Patent Publication No. JP-2018-026974 discloses a cooling device for cooling a motor. The cooling device includes a first flow path for cooling a stator coil, a second flow path for cooling a permanent magnet of a rotor, a distributor for distributing coolant to the first flow path and the second flow path, and a distribution control unit. When a maximum system voltage is supplied to an inverter, an amount of coolant distributed to the first flow path is a first distribution amount, and an amount of coolant distributed to the second flow path is a second distribution amount. When the motor is subjected to field-weakening control, the distribution control unit sets the amount of coolant distributed to the first flow path to be smaller than the first distribution amount, and sets the amount of coolant distributed to the second flow path to be larger than the second distribution amount.

### SUMMARY

Cooling a motor mounted on a vehicle and an inverter driving the motor is considered. According to the technique disclosed in Japanese Laid-Open Patent Publication No. JP-2010-064651, the motor and the inverter are cooled in parallel. The distribution ratio of the cooling water distributed to the motor side and the cooling water distributed to the inverter side is constant.

However, a rotor and a stator of the motor and the inverter may have different heat generation characteristics. It is inefficient to distribute the cooling water to components having different heat generation characteristics at a constant distribution ratio.

For example, consider a situation where a first component and a second component have different heat generation characteristics, the first component is at a relatively high temperature, and the second component is at a relatively low temperature. In order to effectively cool the high-temperature first component, it is necessary to distribute much cooling water to the first component. When the distribution ratio is constant, it is necessary to increase a total flow rate of the cooling water in order to increase the cooling water distributed to the first component. As the total flow rate of the cooling water is increased, the cooling water distributed to the second component also is increased. That is, when the cooling water distributed to the first component is increased, the cooling water distributed to the second component also is increased in conjunction with that. However, a large amount of cooling water is not required to cool the relatively low-temperature second component. It is inefficient to distribute excess cooling water to the second component.

An object of the present disclosure is to provide a technique that can efficiently cool a motor mounted on a vehicle and an inverter driving the motor.

With regard to cooling a motor and an inverter, the inventor of the present disclosure has focused on the following point. There is a difference or similarity in state between a rotor and a stator of the motor and the inverter. For example, the rotor differs from the stator and the inverter in that it performs a rotational motion. On the other hand, the inverter and the stator (stator coil) have in common that a current is supplied thereto from a power source. Such the difference or similarity is considered to lead to a difference or similarity in heat generation characteristics. That is, it is considered that the heat generation characteristics of the inverter and the stator are relatively similar to each other and the heat generation characteristics of the rotor are different from the heat generation characteristics of the inverter and the stator. Therefore, according to the present disclosure, “the inverter-stator pair” and “the rotor” are cooled independently and separately.

A first aspect is directed to a cooling device that cools a motor mounted on a vehicle and an inverter driving the motor.

The cooling device includes:

a common flow path through which coolant flows;

a first flow path branching from the common flow path and arranged to cool the inverter and a stator of the motor;

a second flow path branching from the common flow path, being independent of the first flow path, and arranged to cool a rotor of the motor; and

a distribution structure configured to distribute the coolant to the first flow path and the second flow path, and to change a distribution ratio of a first coolant distributed to the first flow path out of the coolant and a second coolant distributed to the second flow path out of the coolant.

A second aspect further has the following feature in addition to the first aspect.

The first flow path is arranged to cool the inverter and the stator in series.

A third aspect further has the following feature in addition to the second aspect.

The first flow path is arranged such that the inverter is located upstream of the stator in the first flow path.

A fourth aspect further has the following feature in addition to any one of the first to third aspects.

The distribution structure changes the distribution ratio according to a rotational speed of the rotor.

A fifth aspect further has the following feature in addition to the fourth aspect.

A flow rate of the first coolant when the rotational speed is lower than a first rotational speed is greater than a flow rate of the first coolant when the rotational speed is equal to or higher than the first rotational speed.

A flow rate of the second coolant when the rotational speed is equal to or higher than a second rotational speed is greater than a flow rate of the second coolant when the rotational speed is lower than the second rotational speed.

A sixth aspect further has the following feature in addition to the fifth aspect.

When the rotational speed is lower than a third rotational speed, the flow rate of the first coolant is greater than the flow rate of the second coolant.

When the rotational speed is higher than the third rotational speed, the flow rate of the second coolant is greater than the flow rate of the first coolant.

A seventh aspect further has the following feature in addition to any one of the first to sixth aspects.

The rotor includes a rotor shaft and a rotor core around the rotor shaft.

The second flow path includes:

a connection flow path connecting a branch point of the common flow path and the second flow path and the rotor shaft;

a rotor shaft flow path connected to the connection flow path and arranged inside the rotor shaft; and

a rotor core flow path connecting the rotor shaft flow path and an outside of the rotor core through an inside of the rotor core.

The distribution structure includes the branch point, the second flow path, and the rotor.

An eighth aspect is directed to a cooling device that cools a motor mounted on a vehicle and an inverter driving the motor.

The cooling device includes:

a common flow path through which coolant flows;

a first flow path branching from the common flow path and arranged to cool the inverter and a stator of the motor; and

a second flow path branching from the common flow path, being independent of the first flow path, and arranged to cool a rotor of the motor.

The rotor includes a rotor shaft and a rotor core around the rotor shaft.

The second flow path includes:

a connection flow path connecting a branch point of the common flow path and the second flow path and the rotor shaft;

a rotor shaft flow path connected to the connection flow path and arranged inside the rotor shaft; and

a rotor core flow path connecting the rotor shaft flow path and an outside of the rotor core through an inside of the rotor core.

According to the first aspect, the inverter-stator pair is cooled by the first coolant distributed to the first flow path. The inverter and the stator having similar heat generation characteristics can be collectively cooled by the first coolant, which is less wasteful and more efficient. The rotor having different heat generation characteristics is cooled by the second coolant distributed to the second flow path being independent of the first flow path. Furthermore, the distribution ratio of the first coolant and the second coolant is variable. Therefore, when it is desired to increase one of the first coolant and the second coolant, the other of the first coolant and the second coolant is prevented from unnecessarily increasing in conjunction with that. That is, it is possible to suppress a wasteful distribution of the coolant and to efficiently distribute the coolant to the first coolant and the second coolant. It is thus possible to efficiently cool the inverter, the stator, and the rotor.

According to the second aspect, the first flow path is arranged so as to cool the inverter and the stator in series. Since each of the inverter and the stator can be cooled by using the entire first coolant, a cooling efficiency is improved. In addition, since there is no need to further branch the first flow path or further divide the first coolant, a structure related to the first flow path is simplified.

According to the third aspect, the inverter is located upstream of the stator in the first flow path. It is thus possible to more effectively cool the inverter whose maximum allowable temperature is relatively low.

According to the fourth aspect, the distribution ratio is changed according to the rotational speed of the rotor. When the rotational speed is low, heat generations in the inverter and the stator become large. On the other hand, when the rotational speed is high, a heat generation in the rotor becomes large. Changing the distribution ratio according to the rotational speed makes it possible to further efficiently cool the inverter, the stator, and the rotor.

According to the fifth aspect, it is possible to effectively cool the high-temperature inverter and stator in a low-speed region and to save the first coolant in a high-speed region. That is, it is possible to efficiently cool the inverter and the stator. Moreover, it is possible to effectively cool the high-temperature rotor in the high-speed region and to save the second coolant in the low-speed region. That is, it is possible to efficiently cool the rotor.

According to the sixth aspect, a magnitude relationship between the flow rate of the first coolant and the flow rate of the second coolant is reversed between the low-speed region and the high-speed region. It is thus possible to cool the inverter-stator pair and the rotor in a well-balanced manner.

According to the seventh and eighth aspects, the change in the distribution ratio depending on the rotational speed of the rotor is automatically achieved due to the structure of the second flow path arranged inside the rotor. Since control using a controller or the like is unnecessary, a structure of the cooling device is simplified and a manufacturing cost is reduced.

### BRIEF DESCRIPTION OF DRAWINGS

FIG. 1 is a schematic diagram showing a configuration example of a vehicle according to a first embodiment of the present disclosure;

FIG. 2 is a schematic diagram showing a configuration example of a cooling device according to the first embodiment of the present disclosure;

FIG. 3 is a schematic diagram showing a configuration example of an inverter and a first flow path according to the first embodiment of the present disclosure;

FIG. 4 is a schematic diagram showing a configuration example of a motor, a first flow path, and a second flow path according to the first embodiment of the present disclosure;

FIG. 5 is a schematic diagram showing a configuration example of a distribution structure according to the first embodiment of the present disclosure;

FIG. 6 is a conceptual diagram showing an example of a relationship between a coolant flow rate and a rotational speed in the cooling device according to a second embodiment of the present disclosure;

FIG. 7 is a conceptual diagram showing another example of a relationship between a coolant flow rate and a rotational speed in the cooling device according to the second embodiment of the present disclosure;

FIG. 8 is a schematic diagram showing a configuration example of the distribution structure according to the second embodiment of the present disclosure;

FIG. 9 is a schematic diagram showing a configuration example of the distribution structure according to a third embodiment of the present disclosure;

FIG. 10 is a schematic diagram showing a configuration example of the motor, the first flow path, and the second flow path according to a fourth embodiment of the present disclosure; and

FIG. 11 is a schematic diagram showing a configuration example of the cooling device according to a fifth embodiment of the present disclosure.

### EMBODIMENTS

Embodiments of the present disclosure will be described with reference to the attached drawings.

### 1. First Embodiment

### 1-1. Vehicle

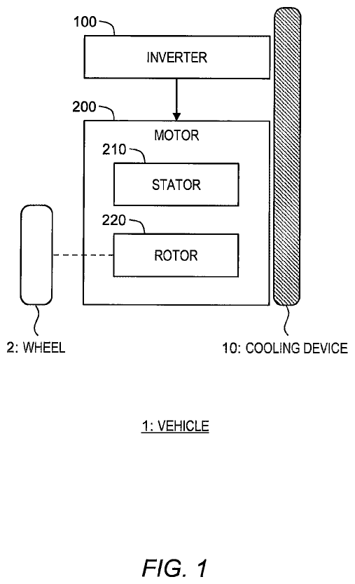

FIG. 1 is a schematic diagram showing a configuration example of a vehicle 1 according to the present embodiment. The vehicle 1 is, for example, an electric vehicle or a hybrid vehicle. An inverter 100 and a motor 200 are mounted on the vehicle 1.

The inverter 100 drives the motor 200. More specifically, the inverter 100 is connected to a power source (not shown), and power is supplied from the power source to the inverter 100. The inverter 100 drives the motor 200 by supplying a motor drive current to the motor 200.

The motor 200 operates (rotates) by being driven by the inverter 100. Examples of the motor 200 include a synchronous motor, an induction motor, a brushless DC motor, and the like. The motor 200 includes a stator 210 and a rotor 220. The motor drive current supplied from the inverter 100 flows through the stator 210 (i.e., a stator coil), and thereby the rotor 220 rotates.

The motor 200 generates a force by rotating. Typically, the motor 200 generates a driving force for the vehicle 1. In this case, the motor 200 generates a torque that rotates wheels 2 of the vehicle 1.

The vehicle 1 is further provided with a cooling device 10 that cools the inverter 100 and the motor 200 (the stator 210 and the rotor 220). Hereinafter, the cooling device 10 according to the present embodiment will be described in more detail.

### 1-2. Cooling Device

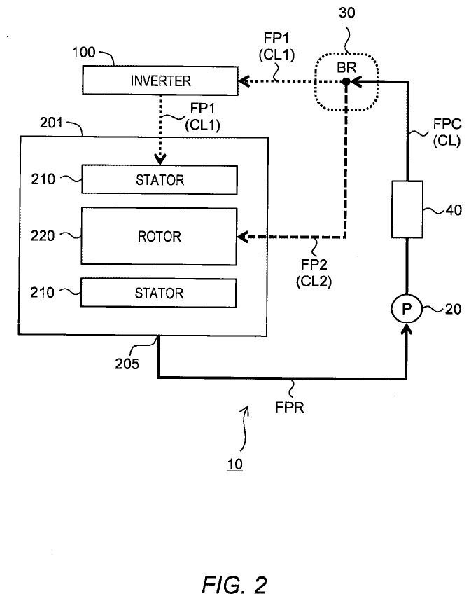

FIG. 2 is a schematic diagram showing a configuration example of the cooling device 10 according to the present embodiment. The cooling device 10 includes a flow path FP through which coolant CL flows, and a pump 20 that feeds the coolant CL into the flow path FP. The coolant CL may be oil or may be water. The flow path FP is arranged so as to cool the inverter 100 and the motor 200 (i.e., the stator 210 and the rotor 220).

With regard to the arrangement of the flow path FP for cooling the inverter 100 and the motor 200, the inventor of the present disclosure has focused on the following point. There is a difference or similarity in state between the inverter 100, the stator 210, and the rotor 220. For example, the rotor 220 differs from the stator 210 and the inverter 100 in that it performs a rotational motion. On the other hand, the inverter 100 and the stator 210 (stator coil) have in common that a current is supplied thereto from a power source. Such the difference or similarity is considered to lead to a difference or similarity in heat generation characteristics. That is, it is considered that the heat generation characteristics of the inverter 100 and the stator 210 are relatively similar to each other and the heat generation characteristics of the rotor 220 are different from the heat generation characteristics of the inverter 100 and the stator 210.

Therefore, according to the present embodiment, independent and separate flow paths are provided for “the inverter 100-stator 210 pair” and “the rotor 220”, respectively. A “first flow path FP1” is for cooling the inverter 100-stator 210 pair. A “second flow path FP2” is for cooling the rotor 220. The first flow path FP1 and the second flow path FP2 are independent of each other.

More specifically, as shown in FIG. 2, the flow path FP includes a common flow path FPC, the first flow path FP1, the second flow path FP2, and a return flow path FPR.

The coolant CL is fed from the pump 20 to the common flow path FPC. In other words, the coolant CL outputted from the pump 20 first flows through the common flow path FPC. The common flow path FPC branches into the first flow path FP1 and the second flow path FP2 at a branch point BR.

The coolant CL flowing through the common flow path FPC is distributed to the first flow path FP1 and the second flow path FP2. A first coolant CL1 is a portion that is distributed to the first flow path FP1 out of the coolant CL. A second coolant CL2 is a portion that is distributed to the second flow path FP2 out of the coolant CL. A structure that distributes the coolant CL flowing through the common flow path FPC to the first flow path FP1 and the second flow path FP2 is hereinafter referred to as a “distribution structure 30.” There are various examples of the distribution structure 30. Some examples of the distribution structure 30 will be described later.

The first flow path FP1 branches from the common flow path FPC at the branch point BR. The first flow path FP1 is arranged so as to cool the inverter 100 and the stator 210. That is, the inverter 100-stator 210 pair is cooled by the first coolant CL1 distributed to the first flow path FP1. The inverter 100 and the stator 210 having similar heat generation characteristics can be collectively cooled by the first coolant CL1, which is less wasteful and more efficient.

In some embodiments, the inverter 100 and the stator 210 may be arranged in series along the first flow path FP1. In other words, the first flow path FP1 may be arranged so as to cool the inverter 100 and the stator 210 in series (in order). In this case, each of the inverter 100 and the stator 210 can be cooled by using the entire first coolant CL1, and thus a cooling efficiency is improved. In addition, since there is no need to further branch the first flow path FP1 or further divide the first coolant CL1, a structure related to the first flow path FP1 is simplified.

In some embodiments, the inverter 100 may be located upstream of the stator 210 in the first flow path FP1. A maximum allowable temperature of the inverter 100 including power elements is lower than that of the stator 210. Since the inverter 100 is located upstream of the stator 210, it is possible to more effectively cool the inverter 100.

In the example shown in FIG. 2, the stator 210 and the rotor 220 of the motor 200 are placed inside a motor case 201. The inverter 100 is placed outside the motor case 201. The first flow path FP1 extends from the branch point BR to the inside of the motor case 201 via the inverter 100. The first coolant CL1 distributed to the first flow path FP1 first cools the inverter 100 and then cools the stator 210 placed inside the motor case 201.

The second flow path FP2 branches from the common flow path FPC at the branch point BR. The second flow path FP2 is independent of the first flow path FP1 and is arranged so as to cool the rotor 220. That is, the rotor 220 is cooled by the second coolant CL2 distributed to the second flow path FP2.

The first coolant CL1 after cooling the stator 210 and the second coolant CL2 after cooling the rotor 220 gather at a bottom of the motor case 201. A outlet 205 for discharging the coolant CL is provided at the bottom of the motor case 201. The return flow path FPR connects the outlet 205 and the pump 20. The coolant CL discharged from the outlet 205 returns to the pump 20 through the return flow path FPR.

The cooling device 10 may include a radiator 40 for cooling the coolant CL. The radiator 40 is provided in the common flow path FPC or the return flow path FPR.

### 1-3. Variable Distribution Ratio

According to the present embodiment, a “distribution ratio R” of the first coolant CL1 distributed to the first flow path FP1 and the second coolant CL2 distributed to the second flow path FP2 is variable. That is, the distribution structure 30 is capable of changing the distribution ratio R of the first coolant CL1 and the second coolant CL2.

As a comparative example, a case where the distribution ratio R is constant is considered. As described above, the heat generation characteristics of the inverter 100 and the stator 210 are relatively similar to each other, and the heat generation characteristics of the rotor 220 are different from the heat generation characteristics of the inverter 100 and the stator 210. Consider a situation where the inverter 100 and the stator 210 are at relatively low temperatures while the rotor 220 is at a relatively high temperature due to the difference in heat generation characteristics. In order to effectively cool the high-temperature rotor 220, it is necessary to increase the second coolant CL2. When the distribution ratio R is constant, it is necessary to increase a total flow rate of the coolant CL in order to increase the second coolant CL2. As the total flow rate of the coolant CL is increased, the first coolant CL1 also is increased. That is, when the second coolant CL2 is increased, the first coolant CL1 also is increased in conjunction with that. However, a large amount of the first coolant CL1 is not required to cool the inverter 100 and the stator 210 of a relatively low temperature. It is inefficient to distribute excess first coolant CL1 to the inverter 100 and the stator 210.

Moreover, in order to increase the total flow rate of the coolant CL, the cooling device 10 is required to have a large structure. For example, a large pipe, a large pump 20, a large radiator 40, and the like are required. Such an increase in size of the cooling device 10 causes an increase in weight and cost. Further, in order to increase the total flow rate of the coolant CL, it is necessary to increase a workload of the pump 20. This leads to a deterioration in fuel efficiency (electricity cost).

On the other hand, according to the present embodiment, the distribution ratio R of the first coolant CL1 for cooling the inverter 100-stator 210 pair and the second coolant CL2 for cooling the rotor 220 is variable. Therefore, when it is desired to increase one of the first coolant CL1 and the second coolant CL2, the other of the first coolant CL1 and the second coolant CL2 is prevented from unnecessarily increasing in conjunction with that. That is, it is possible to suppress a wasteful distribution of the coolant CL and to efficiently distribute the coolant CL to the first coolant CL1 and the second coolant CL2. It is thus possible to efficiently cool the inverter 100, the stator 210, and the rotor 220.

Moreover, according to the present embodiment, an unnecessary increase in the total flow rate of the coolant CL is suppressed. Therefore, miniaturization of the cooling device 10 is possible. The miniaturization of the cooling device 10 provides a reduction in weight and cost. In addition, the increase in workload of the pump 20 for supplying the coolant CL is suppressed which provides an improvement of fuel efficiency.

### 1-4. Configuration Example

### 1-4-1. Configuration Example of Inverter and First Flow Path

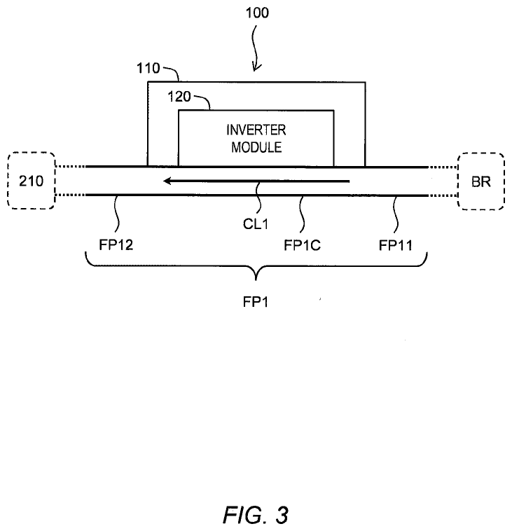

FIG. 3 is a schematic diagram showing a configuration example of the inverter 100 and the first flow path FP1 according to the present embodiment. The inverter 100 includes a case 110 and an inverter module 120 installed in the case 110. The case 110 is made of, for example, metal. The inverter module 120 includes elements necessary for the function of the inverter 100, such as power elements.

The first flow path FP1 is arranged to be in contact with the case 110. More specifically, the first flow path FP1 includes a contact flow path FP1C, an upstream flow path FP11, and a downstream flow path FP12. The contact flow path FP1C is in contact with the case 110 of the inverter 100. The upstream flow path FP11 connects the branch point BR and the contact flow path FP1C. The downstream flow path FP12 is connected downstream of the contact flow path FP1C.

The first coolant CL1 flows through the upstream flow path FP11, the contact flow path FP1C, and the downstream flow path FP12 in this order. The inverter module 120 is cooled by the first coolant CL1 flowing through the contact flow path FP1C.

### 1-4-2. Configuration Example of Motor, First Flow Path, and Second Flow Path

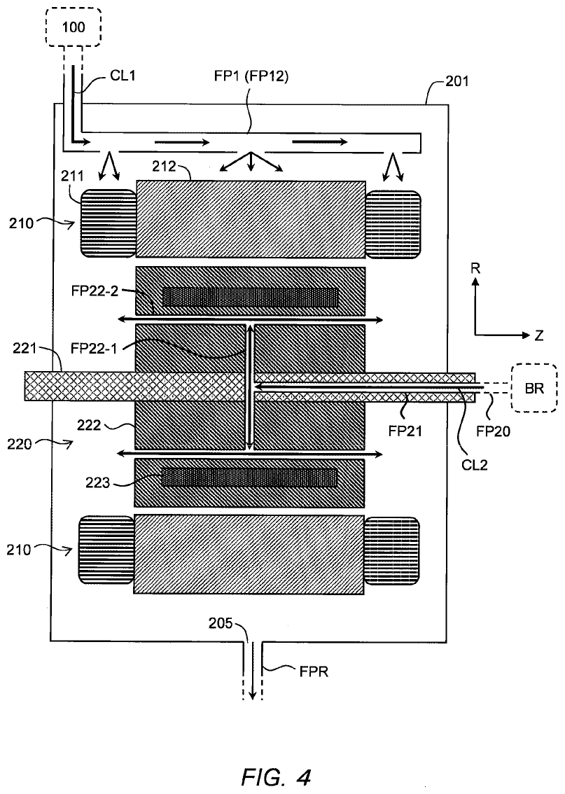

FIG. 4 is a schematic diagram showing a configuration example of the motor 200, the first flow path FP1, and the second flow path FP2 according to the present embodiment. The stator 210 and the rotor 220 of the motor 200 are placed inside the motor case 201. The outlet 205 for discharging the coolant CL is provided at the bottom of the motor case 201.

The stator 210 includes a stator coil 211 and a stator core 212. The motor drive current is supplied to the stator coil 211 from the inverter 100.

The downstream flow path FP12 of the first flow path FP1 is arranged so as to cool at least the stator coil 211. More specifically, the downstream flow path FP12 is arranged in the vicinity of the stator 210. The downstream flow path FP12 has openings at positions facing the stator coil 211. At least a part of the first coolant CL1 flowing through the downstream flow path FP12 is discharged from the openings toward the stator coil 211, thereby cooling the stator coil 211.

Further, another opening may be provided at a position facing the stator core 212. A part of the first coolant CL1 is discharged from the opening toward the stator core 212, thereby cooling the stator core 212. Since the stator core 212 is cooled, the stator coil 211 is indirectly cooled.

The rotor 220 is surrounded by the stator 210. The rotor 220 includes a rotor shaft 221 (rotating shaft), a rotor core 222 around the rotor shaft 221, and a permanent magnet 223 embedded in the rotor core 222. The rotor shaft 221 is rotatably supported by the motor case 201. In the following description, a Z-direction is an axial direction parallel to the rotor shaft 221, and an R-direction is a radial direction orthogonal to the Z-direction.

The second flow path FP2 includes a connection flow path FP20, a rotor shaft flow path FP21, and a rotor core flow path FP22. The connection flow path FP20 connects the branch point BR of the common flow path FPC and the second flow path FP2 and the rotor shaft 221. The rotor shaft flow path FP21 is arranged (formed) inside the rotor shaft 221 and is parallel to the Z-direction. An upstream end of the rotor shaft flow path FP21 is connected to the connection flow path FP20, and a downstream end thereof is connected to the rotor core flow path FP22.

The rotor core flow path FP22 is arranged (formed) inside the rotor core 222. More specifically, the rotor core flow path FP22 connects the downstream end of the rotor shaft flow path FP21 and an outside of the rotor core 222 through the inside of the rotor core 222. In the example shown in FIG. 4, a rotor core flow path FP22-1 extends in the R-direction from the downstream end of the rotor shaft flow path FP21 toward the inside of the rotor core 222. Further, a rotor core flow path FP22-2 extends in the Z-direction from a downstream end of the rotor core flow path FP22-1 toward the outside of the rotor core 222. The rotor core flow path FP22-2 is arranged in the vicinity of the permanent magnet 223 embedded in the rotor core 222.

The second coolant CL2 flows through the connection flow path FP20, the rotor shaft flow path FP21, and the rotor core flow path FP22 in this order, and is eventually discharged to the motor case 201. The rotor 220 is cooled by the second coolant CL2 flowing through the rotor shaft flow path FP21 and the rotor core flow path FP22.

### 1-4-3. Example of Distribution Structure

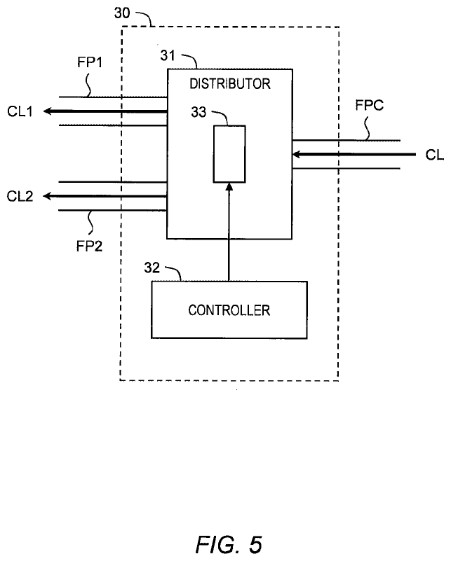

FIG. 5 is a schematic diagram showing a configuration example of the distribution structure 30 according to the present embodiment. The distribution structure 30 includes a distributor 31 and a controller 32.

The distributor 31 is interposed between the common flow path FPC, the first flow path FP1, and the second flow path FP2. The distributor 31 distributes the coolant CL flowing through the common flow path FPC to the first flow path FP1 and the second flow path FP2. Furthermore, the distributor 31 includes a solenoid valve 33. An opening area for the first flow path FP1 and an opening area for the second flow path FP2 are changed by an operation of the solenoid valve 33. In other words, the distribution ratio R of the first coolant CL1 distributed to the first flow path FP1 and the second coolant CL2 distributed to the second flow path FP2 is changed by the operation of the solenoid valve 33.

The controller 32 controls the operation of the solenoid valve 33 of the distributor 31. That is, the controller 32 changes the distribution ratio R of the first coolant CL1 and the second coolant CL2. For example, the controller 32 calculates or acquires a target distribution ratio and controls the operation of the solenoid valve 33 of the distributor 31 such that the target distribution ratio is achieved.

### 2. Second Embodiment

In a second embodiment, “copper loss” and “iron loss” which are causes of heat generation are considered. The iron loss includes hysteresis loss and eddy current loss.

The inverter 100 includes the power elements and a large current flows therein. The motor drive current is supplied to the stator 210 (the stator coil 211). As to the heat generations in such the inverter 100 and the stator 210, the copper loss is dominant. The copper loss increases in proportion to the square of current. Therefore, the heat generations in the inverter 100 and the stator 210 become particularly large in a “low-speed and large-torque region” where the motor drive current is large.

On the other hand, as to the heat generation in the rotor 220 including a magnetic material and performing the rotational motion, the iron loss is dominant. The iron loss increases as a rotational speed N of the rotor 220 increases. Therefore, the heat generation in the rotor 220 becomes particularly large in a “high-speed region.”

As described above, the heat generation characteristics of the inverter 100, the stator 210, and the rotor 220 depend on the rotational speed N of the rotor 220. When the rotational speed N is low, the heat generations in the inverter 100 and the stator 210 become large. On the other hand, when the rotational speed N is high, the heat generation in the rotor 220 becomes large. In the second embodiment, the distribution ratio R is changed according to the rotational speed N in consideration of such the difference in the heat generation characteristics depending on the rotational speed N.

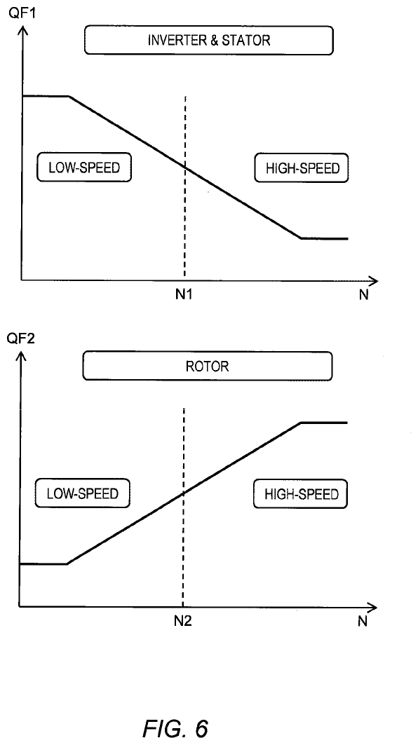

FIG. 6 shows an example of a relationship between a coolant flow rate and the rotational speed N. A horizontal axis represents the rotational speed N of the rotor 220. A vertical axis represents a first coolant flow rate QF1 and a second coolant flow rate QF2. The first coolant flow rate QF1 is a flow rate of the first coolant CL1 distributed to the first flow path FP1. The second coolant flow rate QF2 is a flow rate of the second coolant CL2 distributed to the second flow path FP2. The distribution ratio R corresponds to a ratio of the first coolant flow rate QF1 and the second coolant flow rate QF2.

As shown in FIG. 6, the first coolant flow rate QF1 when the rotational speed N is lower than a first rotational speed N1 is greater than the first coolant flow rate QF1 when the rotational speed N is equal to or higher than the first rotational speed N1. That is, the first coolant flow rate QF1 is relatively large in the low-speed region, and the first coolant flow rate QF1 is relatively small in the high-speed region. It is thus possible to effectively cool the high-temperature inverter 100-stator 210 pair in the low-speed region and to save the first coolant CL1 in the high-speed region. That is, it is possible to efficiently cool the inverter 100 and the stator 210.

On the other hand, the second coolant flow rate QF2 when the rotational speed N is equal to or higher than a second rotational speed N2 is greater than the second coolant flow rate QF2 when the rotational speed N is lower than the second rotational speed N2. That is, the second coolant flow rate QF2 is relatively large in the high-speed region, and the second coolant flow rate QF2 is relatively small in the low-speed region. It is thus possible to effectively cool the high-temperature rotor 220 in the high-speed region and to save the second coolant CL2 in the low-speed region. That is, it is possible to efficiently cool the rotor 220.

Typically, a magnitude relationship between the first coolant flow rate QF1 and the second coolant flow rate QF2 is reversed between the low-speed region and the high-speed region. For example, when the rotational speed N is a third rotational speed, the first coolant flow rate QF1 is equal to the second coolant flow rate QF2. When the rotational speed N is lower than the third rotational speed, the first coolant flow rate QF1 is greater than the second coolant flow rate QF2. On the other hand, when the rotational speed N is higher than the third rotational speed, the second coolant flow rate QF2 is greater than the first coolant flow rate QF1. It is thus possible to cool the inverter 100-stator 210 pair and the rotor 220 in a well-balanced manner.

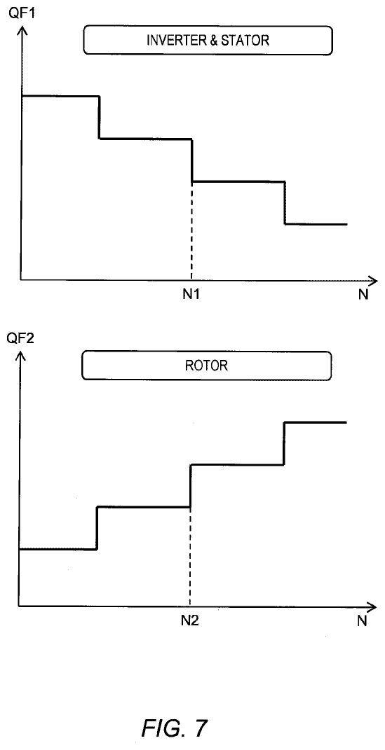

In the example shown in FIG. 6, the first coolant flow rate QF1 decreases as the rotational speed N increases, and the second coolant flow rate QF2 increases as the rotational speed N increases. However, the first coolant flow rate QF1 and the second coolant flow rate QF2 need not necessarily change monotonically. For example, as shown in FIG. 7, the first coolant flow rate QF1 and the second coolant flow rate QF2 may change in a step-by-step manner.

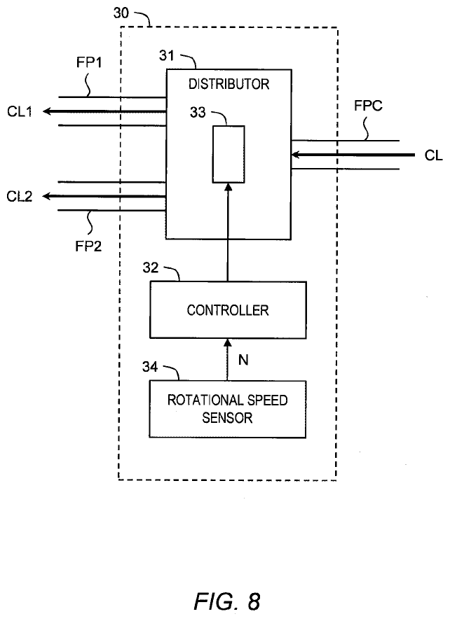

The distribution structure 30 changes the distribution ratio R, that is, the first coolant flow rate QF1 and the second coolant flow rate QF2, according to the rotational speed N of the rotor 220. FIG. 8 shows a configuration example of the distribution structure 30 according to the present embodiment. The controller 32 holds a map indicating the relationship as exemplified in FIGS. 6 and 7. A rotational speed sensor 34 detects the rotational speed N of the rotor 220. The controller 32 receives information on the rotational speed N of the rotor 220 from the rotational speed sensor 34. The controller 32 calculates a target distribution ratio based on the map and the rotational speed N, and controls the distributor 31 such that the target distribution ratio is achieved.

As described above, according to the second embodiment, the heat generation characteristics depending on the rotational speed N of the rotor 220 are taken into consideration. When the rotational speed N is low, the heat generations in the inverter 100 and the stator 210 become large. On the other hand, when the rotational speed N is high, the heat generation in the rotor 220 becomes large. Changing the distribution ratio R of the first coolant CL1 and the second coolant CL2 according to the rotational speed N makes it possible to further efficiently cool the inverter 100, the stator 210, and the rotor 220.

### 3. Third Embodiment

In the third embodiment, another example of the distribution structure 30 will be described. Descriptions overlapping with the above-described embodiments will be omitted as appropriate.

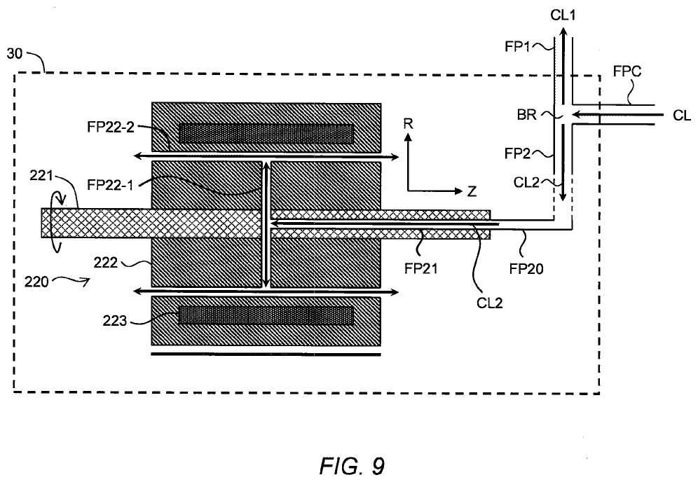

FIG. 9 is a schematic diagram showing a configuration example of the distribution structure 30 according to the third embodiment. FIG. 9 mainly shows a configuration of the rotor 220. The configuration of the rotor 220 is the same as that described in FIG. 4. However, the distributor 31 as shown in FIG. 5 is not provided at the branch point BR.

As described above, the rotor core flow path FP22 extends from the downstream end of the rotor shaft flow path FP21 toward the inside of the rotor core 222. This means that the extending direction of at least a portion of the rotor core flow path FP22 has an R-direction component. In the example shown in FIG. 9, the rotor core flow path FP22-1 extends in the R-direction. When the rotor 220 rotates, a centrifugal force acts on the second coolant CL2 present in the portion having the R-direction component. The centrifugal force promotes the discharge of the second coolant CL2 from the rotor core flow path FP22 to the outside of the rotor core 222. As the discharge of the second coolant CL2 is promoted, drawing of the second coolant CL2 from the common flow path FPC into the second flow path FP2 is promoted. That is to say, when the rotor 220 rotates, the drawing of the second coolant CL2 into the second flow path FP2 due to a negative pressure is promoted.

The centrifugal force and the negative pressure increase as the rotational speed N of the rotor 220 increases. Therefore, as the rotational speed N of the rotor 220 increases, the amount of the drawing of the second coolant CL2 from the common flow path FPC into the second flow path FP2 increases. That is, the second coolant flow rate QF2 increases. When the amount of the drawing of the second coolant CL2 from the common flow path FPC into the second flow path FP2 increases, the first coolant CL1 distributed from the common flow path FPC to the first flow path FP1 decreases accordingly. That is, the first coolant flow rate QF1 decreases.

As described above, as the rotational speed N of the rotor 220 increases, the second coolant flow rate QF2 is automatically increased, and the first coolant flow rate QF1 is automatically decreased. In other words, the relationship as exemplified in the above FIG. 6 is automatically achieved. A desired relationship can be obtained by appropriately designing a length and a diameter of each portion (i.e., the connection flow path FP20, the rotor shaft flow path FP21, and the rotor core flow path FP22) of the second flow path FP2.

The distribution structure 30 distributes the coolant CL flowing through the common flow path FPC to the first flow path FP1 and the second flow path FP2, and changes the distribution ratio R of the first coolant CL1 and the second coolant CL2. In the third embodiment, the branch point BR, the second flow path FP2, and the rotor 220 correspond to such the distribution structure 30.

As described above, according to the third embodiment, the change in the distribution ratio R depending on the rotational speed N of the rotor 220 is automatically achieved due to the structure of the second flow path FP2 arranged inside the rotor 220. The distributor 31 and the controller 32 as shown in the above FIG. 5 are unnecessary. Therefore, the structure of the cooling device 10 is simplified, and a manufacturing cost is also reduced.

### 4. Fourth Embodiment

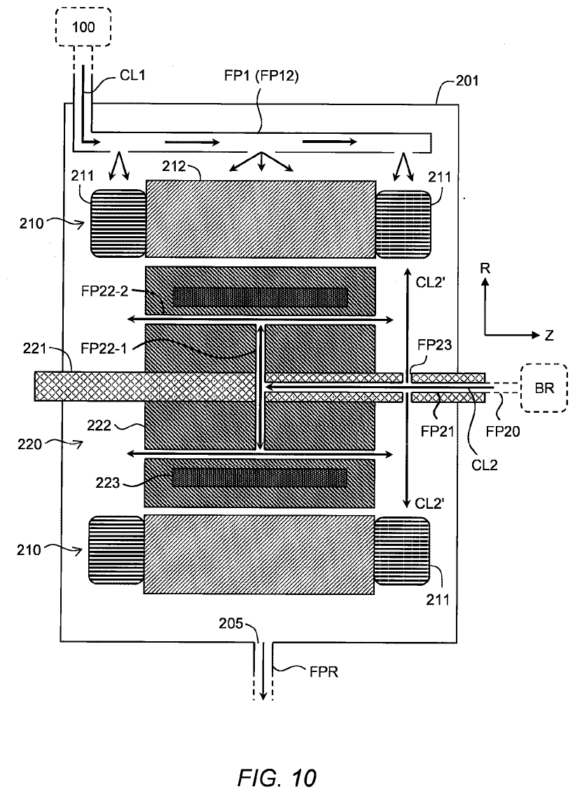

FIG. 10 is a schematic diagram showing a configuration example of the motor 200, the first flow path FP1, and the second flow path FP2 according to a fourth embodiment. Descriptions overlapping with the above-described embodiments will be omitted as appropriate.

As shown in FIG. 10, the second flow path FP2 further includes a rotor shaft flow path FP23 branching from the rotor shaft flow path FP21. The rotor shaft flow path FP23 extends in the R-direction from the rotor shaft flow path FP21 toward the outside of the rotor shaft 221. An external opening of the rotor shaft flow path FP23 is directed to the stator coil 211.

A second coolant CL2′ being a part of the second coolant CL2 flowing through the rotor shaft flow path FP21 is discharged from the rotor shaft flow path FP23 toward the stator coil 211. The second coolant CL2′ supplementarily cools the stator coil 211. This further improves the cooling efficiency of the stator coil 211.

### 5. Fifth Embodiment

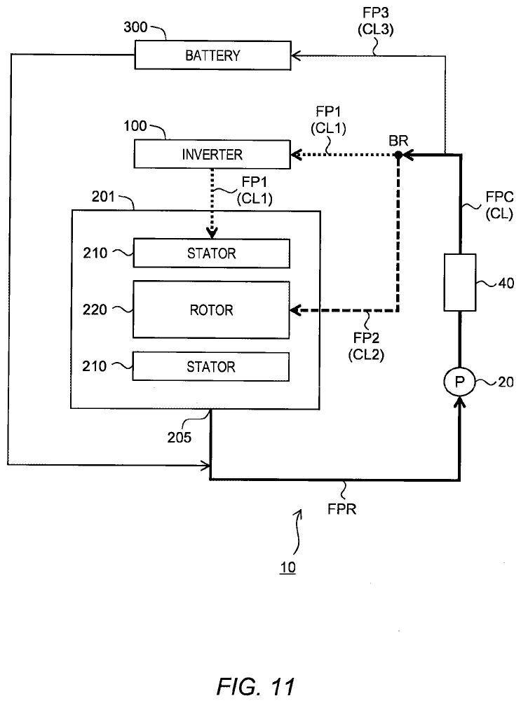

FIG. 11 is a schematic diagram showing a configuration example of the cooling device 10 according to a fifth embodiment. Descriptions overlapping with the above-described embodiments will be omitted as appropriate.

A battery 300 of the vehicle 1 supplies power to the inverter 100, for example. The flow path FP of the cooling device 10 further includes a third flow path FP3 for cooling the battery 300. The third flow path FP3 branches from the common flow path FPC. A third coolant CL3 out of the coolant CL flowing through the common flow path FPC is distributed to the third flow path FP3. The battery 300 is cooled by the third coolant CL3.

According to the fifth embodiment, it is possible to efficiently cool the inverter 100, the motor 200, and the battery 300.

The third flow path FP3 may branch from the first flow path FP1 or the second flow path FP2. In other words, the first flow path FP1 and the second flow path FP2 may branch from the common flow path FPC at different branch points, respectively.

What is claimed is:

1. A cooling device that cools a motor mounted on a vehicle and an inverter driving the motor, the cooling device comprising:
a common flow path through which coolant flows;
a first flow path branching from the common flow path and arranged to cool the inverter and a stator of the motor;
a second flow path branching from the common flow path, being independent of the first flow path, and arranged to cool a rotor of the motor; and
a distribution structure configured to distribute the coolant to the first flow path and the second flow path, and to change a distribution ratio of a first coolant distributed to the first flow path out of the coolant and a second coolant distributed to the second flow path out of the coolant.

2. The cooling device according to claim 1, wherein
the first flow path is arranged to cool the inverter and the stator in series.

3. The cooling device according to claim 2, wherein
the first flow path is arranged such that the inverter is located upstream of the stator in the first flow path.

4. The cooling device according to claim 1, wherein
the distribution structure changes the distribution ratio according to a rotational speed of the rotor.

5. The cooling device according to claim 4, wherein
a flow rate of the first coolant when the rotational speed is lower than a first rotational speed is greater than a flow rate of the first coolant when the rotational speed is equal to or higher than the first rotational speed, and
a flow rate of the second coolant when the rotational speed is equal to or higher than a second rotational speed is greater than a flow rate of the second coolant when the rotational speed is lower than the second rotational speed.

6. The cooling device according to claim 5, wherein
when the rotational speed is lower than a third rotational speed, the flow rate of the first coolant is greater than the flow rate of the second coolant, and
when the rotational speed is higher than the third rotational speed, the flow rate of the second coolant is greater than the flow rate of the first coolant.

7. The cooling device according to claim 1, wherein
the rotor includes a rotor shaft and a rotor core around the rotor shaft,
the second flow path includes:
a connection flow path connecting a branch point of the common flow path and the second flow path and the rotor shaft;
a rotor shaft flow path connected to the connection flow path and arranged inside the rotor shaft; and
a rotor core flow path connecting the rotor shaft flow path and an outside of the rotor core through an inside of the rotor core, and
the distribution structure includes the branch point, the second flow path, and the rotor.

8. A cooling device that cools a motor mounted on a vehicle and an inverter driving the motor, the cooling device comprising:
a common flow path through which coolant flows;
a first flow path branching from the common flow path and arranged to cool the inverter and a stator of the motor; and
a second flow path branching from the common flow path, being independent of the first flow path, and arranged to cool a rotor of the motor, wherein
the rotor includes a rotor shaft and a rotor core around the rotor shaft, and
the second flow path includes:
a connection flow path connecting a branch point of the common flow path and the second flow path and the rotor shaft;
a rotor shaft flow path connected to the connection flow path and arranged inside the rotor shaft; and
a rotor core flow path connecting the rotor shaft flow path and an outside of the rotor core through an inside of the rotor core.
